(19) United States
(12) Patent Application Publication
(10) Pub. No.: US 2025/0062198 A1
(43) Pub. Date: Feb. 20, 2025

(54) DUAL SEMICONDUCTOR DIE CURRENT SENSOR INTEGRATED CIRCUIT

(71) Applicant: Allegro MicroSystems, LLC, Manchester, NH (US)

(72) Inventors: Matthew Hein, Dallas, TX (US); Shixi Louis Liu, Hooksett, NH (US); William P. Taylor, Amherst, NH (US)

(73) Assignee: Allegro MicroSystems, LLC, Manchester, NH (US)

(21) Appl. No.: 18/450,494

(22) Filed: Aug. 16, 2023

(51) Int. Cl. H01L 23/495; H01L 23/00; H01L 23/31; H01L 25/065; H10N 52/80

(52) U.S. Cl. CPC H01L 23/49575; H01L 23/3128; H01L 23/4952; H01L 23/49551; H01L 24/08; H01L 24/48; H01L 25/0657; H10N 52/80; H01L 2224/08225; H01L 2224/48091; H01L 2224/48247; H01L 2924/182

(57) ABSTRACT

A current sensor IC includes a lead frame having a first surface, a second opposite surface and including a primary conductor and signal leads. A first semiconductor die has a first surface adjacent to the first surface of the lead frame and supporting a first magnetic field sensing element and a second semiconductor die has a first surface adjacent to the second surface of the lead frame and a second opposite surface supporting a second magnetic field sensing element. Fabrication methods include a single mold method and a two-mold method in which a mold material can provide isolation between the first semiconductor die and the primary conductor. Also described is a current sensor IC in which both first and second semiconductor die are arranged in a flip-chip configuration. Diagnostic circuits and inter-die connections permit one semiconductor die to sense faults with the other semiconductor die.

### BACKGROUND

Some current sensor integrated circuits include one or more magnetic field sensing elements in proximity to an integrated current-carrying primary conductor. The magnetic field sensing elements generate an output signal having a magnitude proportional to the magnetic field induced by the current through the conductor.

In applications in which the primary conductor can be at a relatively high voltage, safety specifications require that a certain electrical isolation be maintained between the primary conductor and other parts of the circuitry (e.g., signal leads coupled to an external system to which the sensor output signal is communicated). For example, safety specifications can dictate a minimum “creepage” that refers to the shortest distance between two conductive parts along the surface of any insulation material common to the two conductive parts and/or a minimum “clearance” that refers to the shortest distance through air between the two conductive parts. The creepage requirement is based on the distance necessary to withstand a given working voltage (i.e., the highest voltage level that insulation under consideration can be subjected to when the current sensor is operating in normal use).

Current sensor integrated circuits are used in automobile control systems and other safety critical applications. There are a variety of specifications that set forth requirements related to permissible sensor quality levels, failure rates, and overall functional safety. One approach to meeting such mandates has been to use redundant, identical circuits in a sensor integrated circuit. Another approach to meeting a high level of safety standard compliance involves using more than one different (i.e., heterogenous) sensing elements, circuitry and/or methodologies.

### SUMMARY

Described herein are structures and methods directed towards providing current sensor integrated circuits (ICs) that include sensing redundancy to meet safety requirements and that meet electrical isolation requirements for high voltage applications and high current applications. The described current sensor ICs include two semiconductor die supporting current sensing elements and/or circuitry. The described dual-die current sensor ICs facilitate electrical connection between the die with which diagnostics can be implemented.

According to the disclosure, a current sensor integrated circuit (IC) includes a lead frame having a first surface and a second surface opposite to the first surface and including a primary conductor and signal leads. A first semiconductor die has a first surface adjacent to the first surface of the lead frame and a second opposite surface, wherein the first semiconductor die includes a first magnetic field sensing element supported by the first surface of the first semiconductor die and configured to sense a magnetic field associated with a current through the primary conductor and to generate a first output signal indicative of the current for coupling to a first signal lead. A second semiconductor die has a first surface adjacent to the second surface of the lead frame and a second opposite surface, wherein the second semiconductor die includes a second magnetic field sensing element supported by the second surface of the second semiconductor die and configured to sense the magnetic field associated with the current through the primary conductor and to generate a second output signal indicative of the current for coupling to a second signal lead.

Features may include one or more of the following individually or in combination with other features. The current sensor IC can include a solder bump or copper pillar to couple the first output signal to the first signal lead and a wire bond to couple the second output signal to the second signal lead. The current sensor IC can further include a mold material configured to enclose the first semiconductor die, the second semiconductor die, and a portion of the lead frame to form a package. The current sensor IC can further include a first mold material to enclose the first semiconductor die and a portion of the lead frame, wherein the second semiconductor die is attached to the first mold material and wherein the current sensor IC further includes a second mold material to enclose the second semiconductor die. The first output signal can be indicative of the current within a first range of currents, wherein the second output signal is indicative of the current within a second range of currents, and wherein the first range of currents can be the same as or different than the second range of currents. The current sensor IC can further include a first insulation structure disposed between the primary conductor and the first semiconductor die and a second insulation structure disposed between the primary conductor and the second semiconductor die. Each of the first insulation structure and the second insulation structure can include a polymer film. Each of the first insulation structure and the second insulation structure can further include an adhesive layer. The polymer film and the adhesive layer can be provided as a tape. The tape can extend beyond a periphery of the first semiconductor die and the second semiconductor die. The tape can extend beyond the primary conductor adjacent to the signal leads by 0.4 mm. The current sensor IC can further include an attachment material to attach the first semiconductor die to the first insulation structure and to attach the second semiconductor die to the second insulation structure. The attachment material can include a non-conductive adhesive. The primary conductor can include at least one notch and wherein the first magnetic field sensing element can be substantially vertically aligned with a first side of the at least one notch and the second magnetic field sensing element can be substantially vertically aligned with a second side of the at least one notch supported by the semiconductor die. The signal leads include signal leads associated with the first semiconductor die and signal leads associated with the second semiconductor die, wherein one or both of the first semiconductor die and the second semiconductor die can further include a diagnostic circuit having an input coupled to a signal lead associated with the other one of the first semiconductor die and the second semiconductor die and configured to generate a diagnostic signal indicative of a status of the other one of the first semiconductor die and the second semiconductor die.

Also described is a current sensor integrated circuit (IC) including a lead frame having a first surface and a second surface opposite to the first surface and including a primary conductor and signal leads. A first semiconductor die has a first surface adjacent to the first surface of the lead frame and a second opposite surface, wherein the first semiconductor die includes a first magnetic field sensing element supported by the first surface of the first semiconductor die and configured to sense a magnetic field associated with a current through the primary conductor and to generate a first output signal indicative of the current for coupling to a first signal lead. A second semiconductor die has a first surface adjacent to the second surface of the lead frame and a second opposite surface, wherein the second semiconductor die includes a second magnetic field sensing element supported by the first surface of the second semiconductor die and configured to sense the magnetic field associated with the current through the primary conductor and to generate a second output signal indicative of the current for coupling to a second signal lead.

Features may include one or more of the following individually or in combination with other features. The current sensor IC can further include a first solder bump or copper pillar to couple the first output signal to the first signal lead and a second solder bump or copper pillar to couple the second output signal to the second signal lead. The current sensor IC can further include a mold material configured to enclose the first semiconductor die, the second semiconductor die, and a portion of the lead frame to form a package.

Also described is a method of manufacturing a current sensor integrated circuit (IC) including providing a lead frame having a first surface and a second surface opposite to the first surface with a primary conductor and signal leads, positioning a first semiconductor die adjacent to the first surface of the lead frame, and positioning a second semiconductor die adjacent to the second surface of the lead frame. The first semiconductor die is associated with a first plurality of the signal leads and includes a first magnetic field sensing element to sense a magnetic field associated with a current through the primary conductor and to generate a first output signal indicative of the current for coupling to one or more of the first plurality of signal leads. The second semiconductor die is associated with a second plurality of the signal leads and includes a second magnetic field sensing element to sense the magnetic field associated with the current through the primary conductor and to generate a second output signal indicative of the current for coupling to one or more of the second plurality of signal leads. The first semiconductor die includes a diagnostic circuit having an input coupled to one or more of the second plurality of signal leads and configured to generate a first diagnostic signal indicative of a status of the second semiconductor die.

Features may include one or more of the following individually or in combination with other features. The second plurality of signal leads can include one or more of a supply connection, a ground connection, or an output connection.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 is a side view of a current sensor IC including a flip-chip die and a die-up die according to aspects of the disclosure;

FIG. 1A is a top perspective view of the current sensor IC of FIG. 1;

FIG. 1B is a bottom perspective view of the current sensor IC of FIG. 1;

FIG. 1C is a top plan view of the current sensor IC of FIG. 1;

FIG. 1D is a top plan view of a current sensor IC similar to the IC of FIG. 1, but with an alternative lead type;

FIG. 1E is a side view of the current sensor IC of FIG. 1D;

FIGS. 2, 2A, and 2B illustrate an example two mold fabrication process for providing the current sensor IC of FIG. 1 for high isolation applications;

FIGS. 2C, 2D, and 2E illustrate an example two mold fabrication process for providing the current sensor IC of FIG. 1 for lower isolation applications;

FIG. 3 is a side view of a current sensor IC including two flip-chip die according to aspects of the disclosure;

FIG. 3A is a top perspective view of the current sensor IC of FIG. 3;

FIG. 3B is a bottom perspective view of the current sensor IC of FIG. 3;

FIG. 3C is a top plan view of the current sensor IC of FIG. 3;

FIG. 3D is a top plan view of a current sensor IC similar to the IC of FIG. 3, but with an alternative lead type;

FIG. 3E is a side view of the current sensor IC of FIG. 3D; and

FIG. 4 is a schematic block diagram of an example current sensor IC including diagnostics according to aspects of the disclosure.

### DETAILED DESCRIPTION

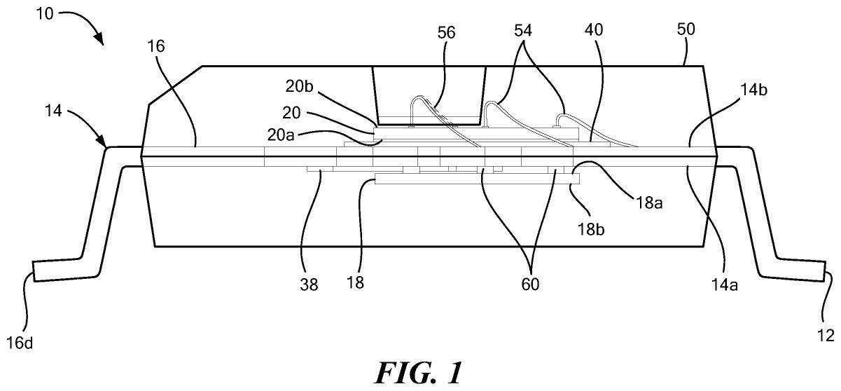

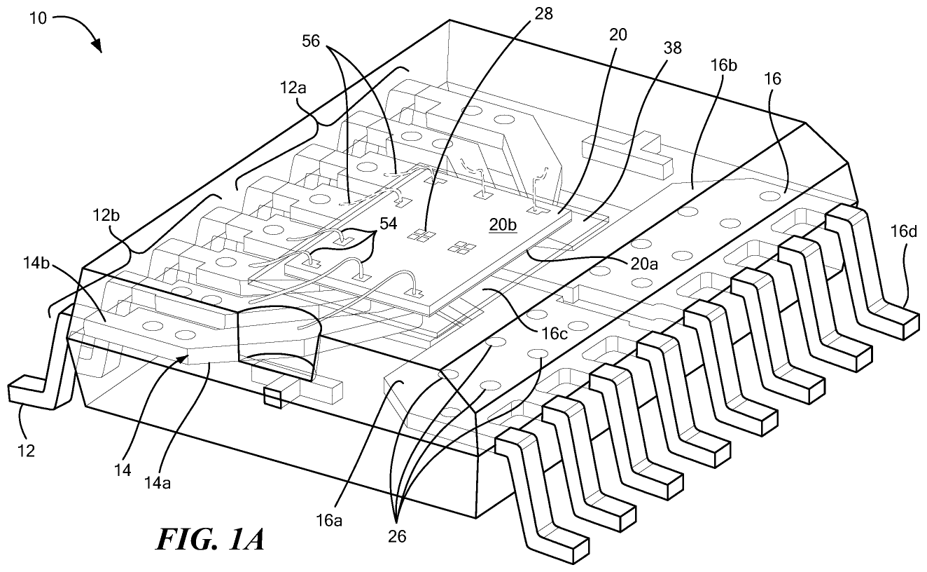

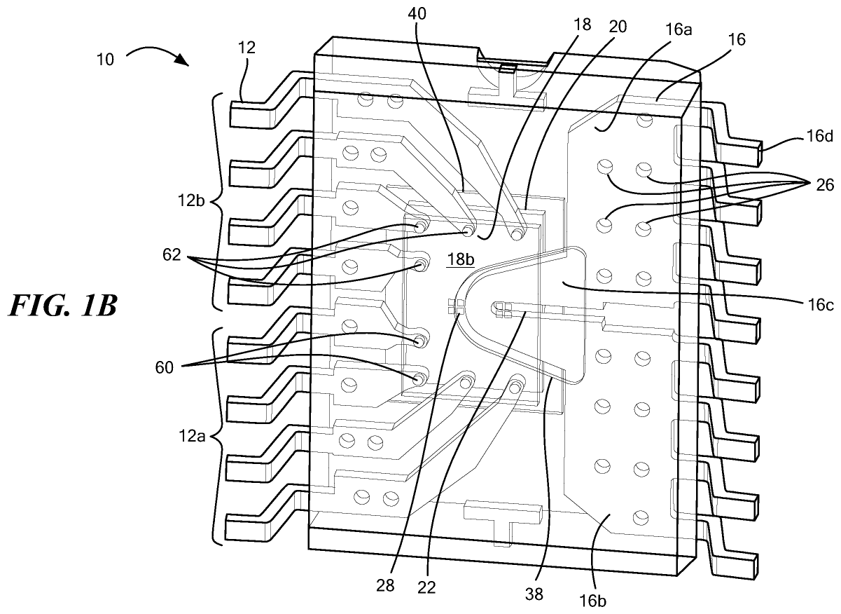

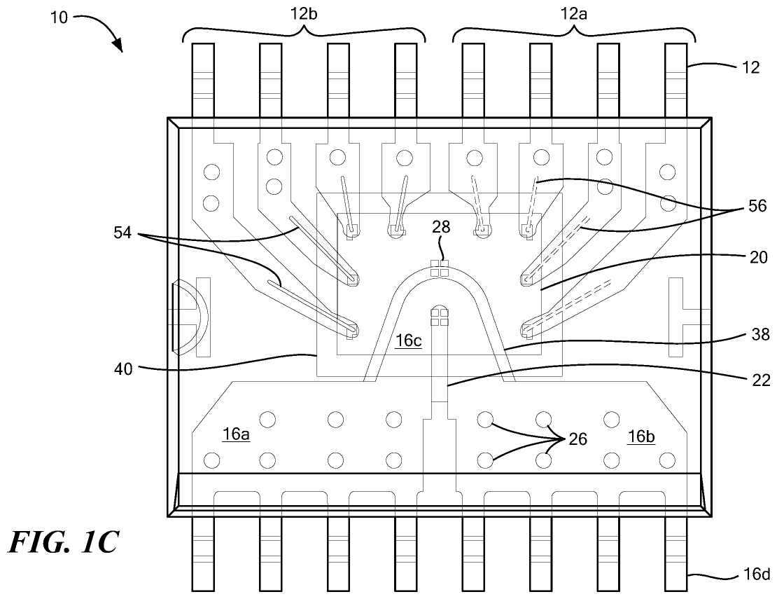

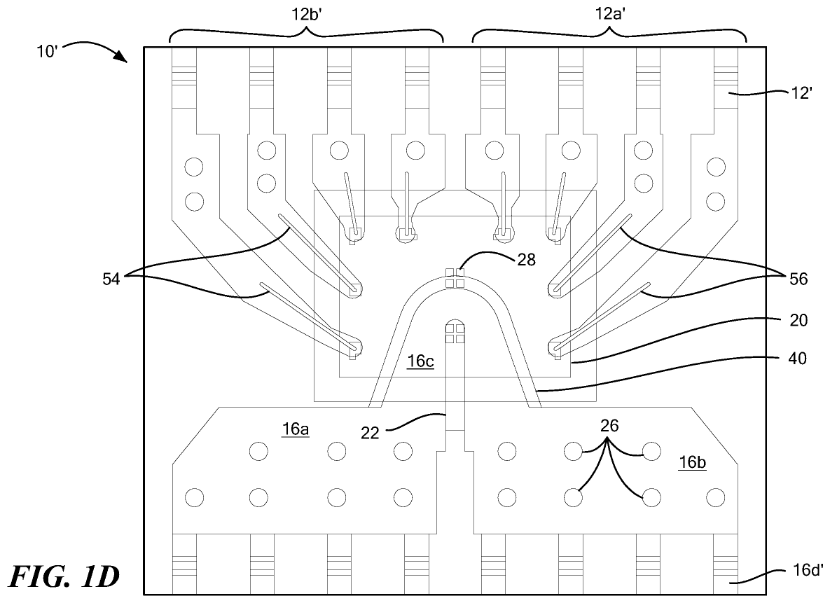

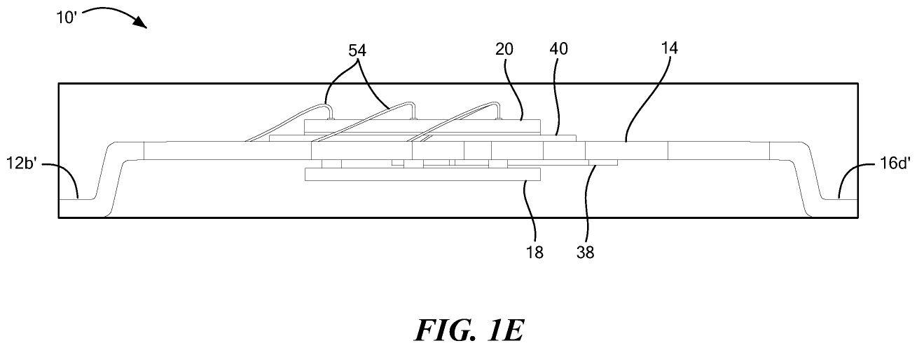

Referring to the various views of FIGS. 1-1C, a current sensor integrated circuit (IC) 10 includes a lead frame 14 having a first surface 14a and a second surface 14b opposite to the first surface, with a first semiconductor die 18 adjacent to the first surface 14a and a second semiconductor die 20 adjacent to the second surface 14b. The lead frame 14 further includes a primary conductor 16 and a plurality of signal leads, collectively labeled 12. Signal leads 12 include a first signal lead set 12a associated with the first die 18 and a second signal lead set 12b associated with the second die 20. It will be appreciated by those of ordinary skill in the art that although the lead frame 14 is shown to have eight signal leads, with four such leads forming the first signal lead set 12a and four such leads forming the second signal lead set 12b, other numbers, dimensions, spacing, and configurations of leads are possible.

The first semiconductor die 18 has a first surface 18a adjacent to the first surface 14a of the lead frame 14 and a second opposite surface 18b. The first semiconductor die 18 includes a first magnetic field sensing element 24 supported by the first surface 18a of the first semiconductor die 18 and configured to sense a magnetic field associated with a current through the primary conductor 16 to generate a first output signal indicative of the current for coupling to a first signal lead 12a. The second semiconductor die 20 has a first surface 20a adjacent to the second surface 14b of the lead frame 14 and a second opposite surface 20b. The second semiconductor die 20 includes a second magnetic field sensing element 28 supported by the second surface 20b of the second semiconductor die 20 and configured to sense the magnetic field associated with the current through the primary conductor 16 and generate a second output signal indicative of the current for coupling to a second signal lead 12b.

With this arrangement, the first die 18 is arranged in a so-called flip-chip configuration with which the sensing element 24 is supported by a die surface 18a proximal to the lead frame 14 and the second die 20 is arranged in a so-called die-up configuration with which the sensing element 28 is supported by a die surface 20b distal from the lead frame 14. It will be appreciated by those of ordinary skill in the art that while the bottom semiconductor die 18 (i.e., the die positioned below the lead frame 14 in FIG. 1) is shown to have a flip-chip configuration and the top semiconductor die 20 (i.e., the die positioned above the lead frame 14 in FIG. 1) is shown to have a die-up configuration, this arrangement can be reversed so that the top semiconductor die has the flip-chip configuration and the bottom semiconductor die has the die-up configuration. Additionally, it will be appreciated by those of ordinary skill in the art that the first die 18 can, alternatively, be connected with wire bonds from the first surface 18a of the die 18 to bond pads on the second surface 14b of the lead frame 14 in a so-called Lead-on-Chip (LOC) configuration.

Use of different mounting methodologies (i.e., flip-chip, lead on chip, or die-up, also known as chip on lead) provides heterogeneous safety integrity in the sense that a failure of one mounting methodology does not necessarily tend to suggest, or result in a failure of the other mounting methodology. Additionally, failure modes to which one mounting methodology may be susceptible are less a factor or non-existent in the other mounting methodology. For example, bond wire failure for a die-up configuration is not a possible failure mode for a flip-chip die because bond wires are not used.

The above-described arrangement permits the semiconductor die 18, 20 to be redundant in the sense that each die can detect the magnetic field associated with current flow through the primary conductor 16 and provide a respective output signal indicative of the sensed current. Such redundant current sensing can be accomplished by identical sensing elements and/or processing circuitry on the two die 18, 20 or there can be one or more differences between the sensing elements and/or processing circuitry implemented by the two die 18, 20. Designing the two die 18, 20 with different sensing elements and/or processing circuitry can achieve so-called heterogeneous redundancy that can increase the level of safety integrity.

Because one sensing element 24 is supported by a die surface 20b that is distal from lead frame surface 14b and the other sensing element 28 is supported by a die surface 18a that is proximal to the opposite lead frame surface 14b, the coupling of the magnetic field to the two sensing elements 24, 28 will be different, although not substantially different. For sensing elements and processing circuitry designed to have the same properties, including sensitivity, in some embodiments, one of the die 18, 20 can detect current levels within a first range of currents and the other die can detect current levels within a second range of currents that is the same as or different than the first range of currents but with significant overlap. In embodiments in which it is desired that both die 18, 20 detect the same current, the processing circuitry on one or both die can be programmed to have different sensitivities in order to account for the difference in magnetic coupling to the sensing elements 24, 28, respectively. Because the distances between the primary conductor 16 and each of the sensing elements 24, 28 are slightly different, in embodiments, this difference and the resulting difference in magnetic coupling to each sensing element 24, 28 can be used to check one die versus the other and prevents some common-cause failures of device test & trim because each sensitivity must be configured to account for the difference in coupling factor. In another embodiment different, types of magnetic field sensing elements may be used on different, or within the same die, such as Hall with GMR or TMR.

Each of the magnetic field sensing elements 24, 28 can be a single element or can include more than one element, such as a dual Hall element or a quad Hall element or one or more MR elements such as GMR or TMR elements as are sometimes arranged in a bridge configuration and as may be used to implement differential magnetic field sensing. It will be appreciated that although the first semiconductor die 18 is described as supporting a first magnetic field sensing element 24 and the second semiconductor die 20 is described as supporting a second magnetic field sensing element 28, in embodiments, it is possible for only one of the die 18, 20 to support one or more magnetic field sensing elements and the other die to support processing circuitry.

As used herein, the term “magnetic field sensing element” is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

The primary conductor 16 may have various shapes and dimensions to accommodate a range of current levels sought to be detected by the current sensor 10 and the desired IC package footprint. In general, primary conductor 16 includes an input portion 16a, an output portion 16b, and a thinned current path 16c between the input and output portions. In use, a current flow is established through the primary conductor 16 between the input and output portions 16a, 16b.

The input and output portions 16a. 16b of the primary conductor 16 can have respective terminal ends in the form of leads, collectively labeled 16d, configured for electrical connection to a printed circuit board (PCB) or other substrate on which the IC 10 is mounted. The leads 16d of the primary conductor 16 and signal leads 12a, 12b can take various forms, such as the illustrated leads that are bent to facilitate surface mount solder connection to a PCB or other substrate. Current sensor IC 10 can be considered an SOIC (Small Outline Integrated Circuit) package. Other package types, such as QFN (Quad-Flat No-Leads), or the DFN (Dual-Flat No-Leads) sensor IC 10′ of FIGS. 1D and 1E, are possible.

The thinned current path 16c of the primary conductor 16 can have various shapes and other characteristics. Here, the thinned path 16c is curved in a “horseshoe” shape and to form a notch 22. Placement of the sensing elements 24, 28 relative to the curved, thinned current path 16c and notch 22 can concentrate the magnetic field generated by current through the primary conductor 16 on the sensing elements. It will be appreciated that other shapes, dimensions, notches, and sensing element placement can be implemented to achieve concentration of the magnetic field.

In embodiments, the first magnetic field sensing element 24 can include one or more elements that are substantially vertically aligned with a first side of the notch 22 and one or more elements that are substantially vertically aligned with a second side of the notch 22. Similarly the second magnetic field sensing element 28 can include one or more elements that are substantially vertically aligned with a first side of the notch 22 and one or more elements that are substantially vertically aligned with a second side of the notch 22. As current flows through the primary conductor 16, having magnetic field sensing elements 24, 28 positioned to the sides of the conductor (rather than directly over or under the conductor) results in magnetic field with components perpendicular to the die 18, 20 such that the sensing elements may be planar Hall effect elements. In other embodiments, the magnetic field sensing element or elements may be positioned directly over or under the primary conductor 16 to sense magnetic field components parallel to the surface of die 18, 20, in which case sensing elements such as a vertical Hall element, a GMR, TMR, or AMR element may be used.

The lead frame 14 can be comprised of a conductive material, such as copper or copper alloy or Aluminum, and its features can be formed by various methods such as stamping or etching.

Electrical isolation between the primary conductor 16 and the first, flip-chip semiconductor die 18 can be achieved with various mechanisms, such as with an insulating layer 38 disposed between the primary conductor and the first surface 18a of the first semiconductor die. Similarly, electrical isolation between the primary conductor 16 and the second semiconductor die 20 can be achieved with various mechanisms, such as with an insulating layer 40 disposed between the primary conductor and the first surface 20a of the second semiconductor die 20.

One or both of insulating layers 38, 40 can include an organic polymer such as polyimide, or an oxide insulating material like silicon dioxide in the form of a glass sheet, or ceramic. For example, insulating layers 38, 40 can be a polymer film, as may be provided in the form of a polyimide or Kapton® tape, as non-limiting examples. The insulating layers 38, 40 may include an adhesive layer, in which case the polymer film and the adhesive layer may be provided as a tape with which the insulating layers are attached to the lead frame 14 and such an adhesive layer can itself provide insulation.

Insulating layers 38, 40 can extend beyond the periphery of the respective semiconductor die 18, 20 and/or primary conductor 16 so as to achieve a required clearance specification. For example, in embodiments, the insulating layers 38, 40 may extend beyond the respective die 18, 20 and/or primary conductor 16 by a distance of at least 0.4 mm. The overall size and shape of the insulation layers 38, 40 can vary with the size/shape of the die 18, 20 and primary conductor 16.

An attachment material can be provided to mechanically attach the first semiconductor die 18 to the first insulation structure 38 and to mechanically attach the second semiconductor die 20 to the second insulation structure 40. In some embodiments, die 18, 20 are attached to respective insulation structures 38, 40 by an adhesive layer of the insulating structures 38, 40 themselves (i.e., an adhesive layer of an insulating tape). In some embodiments, die 18, 20 are attached to respective insulation structures 38, 40 by a non-conductive adhesive, such as wafer backside coating or dispensed epoxy or a combination of both wafer backside coating and dispensed non-conductive epoxy, as non-limiting examples. And in some embodiments, wafer backside coating can replace the insulation structure 40.

Flip-chip configured semiconductor die 18 can be electrically and mechanically coupled to the lead frame 14 by various mechanisms, including bumps 60 as can be solder bumps or copper pillars, as non-limiting examples, with which die 18 is connected to leads 12a. The solder may be a Sn Pb solder or a lead less solder, such as an Indium solder. One or more bumps 60 can be so-called “dummy” bumps, in that they provide only mechanical attachment and/or stability rather than both mechanical and electrical coupling. In the case of a dummy bump, the bond pad to which the dummy bump is connected is not electrically connected to the circuitry on the die. Such electrical isolation may be achieved with materials including, but not limited to an oxide, a nitride, or a polymer isolation layer or combinations thereof.

Die-up configured semiconductor die 20 can be electrically coupled to the lead frame 14 by wire bonds 54 with which die 20 is connected to leads 12b. To this end, areas of the surface 14b of the lead frame 14 can be plated to accept a solder connection of wire bonds 54, such as with silver.

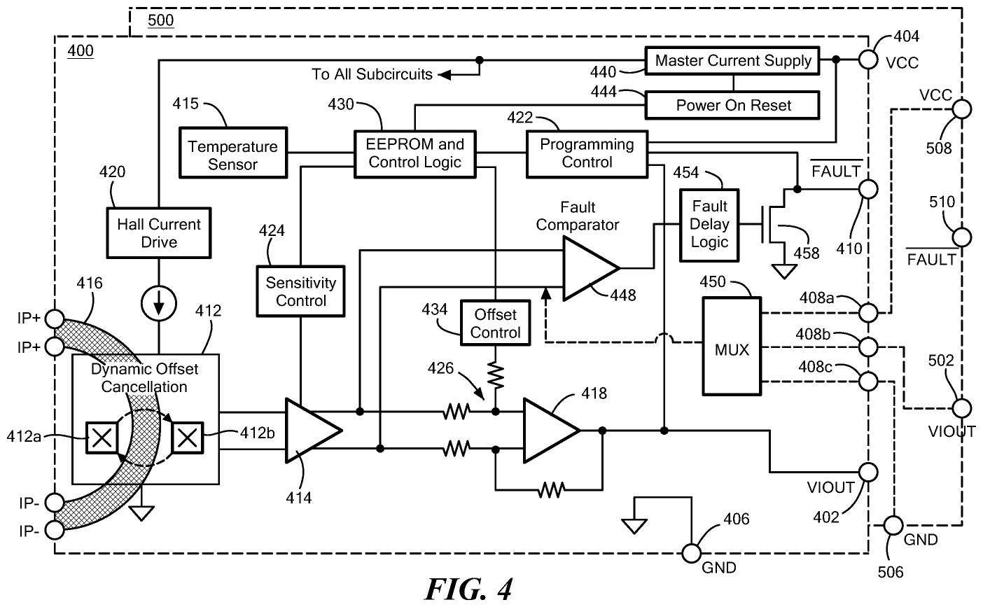

According to an aspect of the disclosure, the dual-die current sensor IC 10 facilitates electrical connection between the die 18, 20 with which diagnostics can be implemented. As illustrated in FIG. 4, one or both of the first semiconductor die 18 and the second semiconductor die 20 can include a diagnostic circuit having one or more diagnostic inputs coupled to a signal lead 12b, 12a associated with the other one of the first and second die and configured to generate a diagnostic signal indicative of a status of the other one of the first and second die. To this end, wire bonds 56 can electrically couple die 20 to signal leads 12a associated with the die 18 and/or bumps 62 can electrically couple die 18 to signal leads 12b associated with the die 20.

Insulating material 50 can take the form of a mold material configured to encapsulate the first and second semiconductor die 18, 20, and portions of the lead frame 14 in order to form the packaged current sensor IC 10. The mold material 50 is shown to illustrate elements encapsulated within the IC package 10. Various materials can be used to form the mold material 50, including, but not limited to a plastic material.

Portions of the lead frame 14 can include features configured to enhance adhesion of the mold material 50 to the lead frame, thereby serving as a “locking mechanism” to secure parts of the IC package together. Here, holes 26 through the primary conductor 16 and signal leads 12 can provide such a locking mechanism.

In some embodiments, fabrication of the current sensor 10 can be accomplished by first attaching the flip-chip die 18 to the surface 14a of the lead frame. This step can include attaching the insulating layer 38 to the primary conductor 16 and soldering bumps or copper pillars 60 to plated areas of the surface 14a of the lead frame 14 for electrical connection to signal leads 12a. In the case of inter-die diagnostics, bump connections 62 between the first die 18 and the signal leads 12b associated with the second die 20 can be made.

The subassembly thus including the lead frame 14, the insulating layer 38, and the die 18 can then then be flipped over to facilitate attachment of the second die 20 to the surface 14b of the lead frame. This step can include attachment of the insulating layer 40 to the primary conductor 16 and attachment of the die surface 20a to the insulating layer 40. Thereafter, wire bond connections 54 between the second die 20 and the signal leads 12b can be made to plated areas, or bond pads on the surface 14a of the lead frame. In the case of inter-die diagnostics, wire bond connections 56 between the second die 20 and the signal leads 12a associated with the first die 18 can be made to plated areas, or bond pads on the surface 14a.

It will be appreciated by those of ordinary skill in the art that in some embodiments, it may not be desirable to connect signal leads of one die to the other die (e.g., in the case of an output voltage pin or an output current pin).

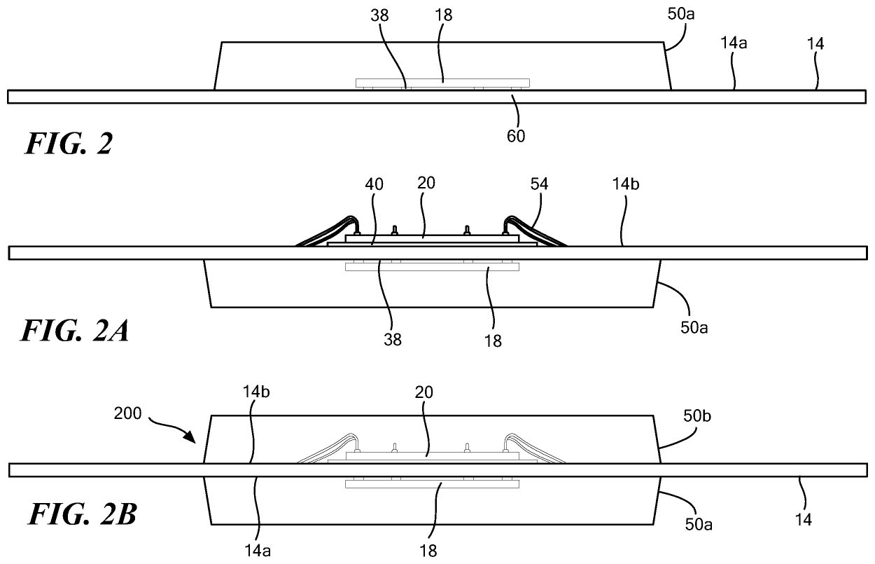

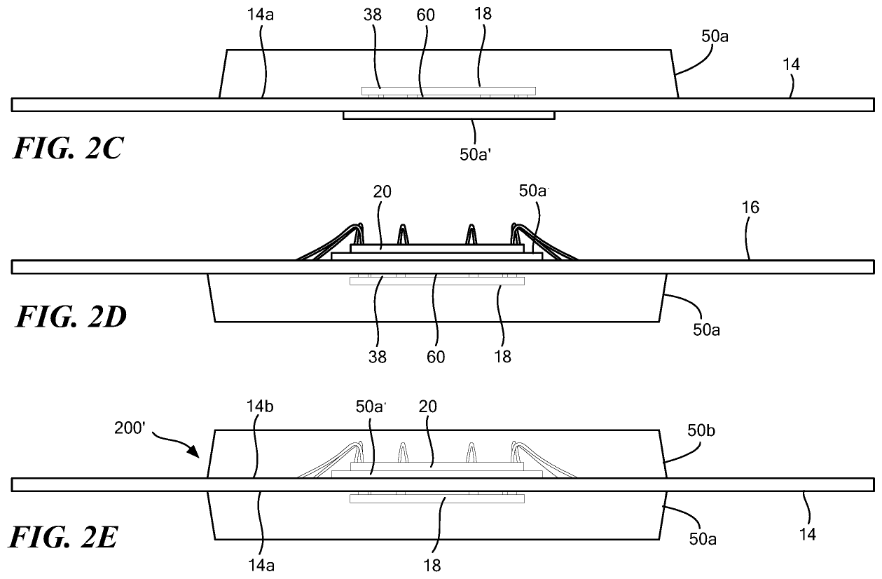

The entire structure, excluding terminal ends of the signal leads 12 and primary leads 16d, can be overmolded with mold material 50 in a mold process step, following which terminal ends of primary conductor leads 16d and signal leads 12 can be bent, as shown. The mold material 50 can be formed by a transfer mold process, as may include a single mold process step. In some embodiments, more than one mold process step is used, such as will be described in connection with FIGS. 2-2E. It will be appreciated by those of ordinary skill in the art that the order of the above-described steps can be varied.

Referring also FIGS. 1D and 1E, an alternative current sensor IC 10′ can be a DEN package, but in other respects can be the same as or similar to current sensor IC 10 (and thus, like reference numbers are used for like elements). To this end, the terminal ends of primary conductor leads 16d′ are conductive pads exposed from side and bottom surfaces of the package 10′ and the signal leads 12a′, 12b′ are likewise conductive pads exposed from side and bottom surfaces of the package 10′. Accordingly, as shown in the side view of FIG. 1E, the leads 12a′. 12b′, 16d′ are upset. In other respects, the DFN package of FIGS. 1D and 1E can be the same as the SOIC package of FIGS. 1-1C.

Referring to FIGS. 2-2E, dual mold processes are illustrated for manufacturing a current sensor IC that can be the same as or similar to current sensor IC 10 in FIG. 1. Thus, the current sensor ICs fabricated according to the two mold processes of FIGS. 2-2E include a first die 18 in a flip-chip orientation and a second die 20 in a die-up orientation and like reference numbers are used for like elements. FIGS. 2, 2A, and 2B illustrate a two mold process to fabricate a current sensor IC 200 for applications requiring higher electrical isolation and FIGS. 2C, 2D, and 2E illustrate an alternative two mold process to fabricate a current sensor IC 200′ for applications requiring lower electrical isolation.

In FIG. 2, flip-chip die 18 is attached to the surface 14a of the lead frame 14 by attaching the insulating layer 38 to the primary conductor 16 and soldering bumps or copper pillars 60 to plated areas of the surface 14a of the lead frame 14 for electrical connection to signal leads associated with the first die (e.g., signal leads 12a in FIG. 1B). In the case of inter-die diagnostics, bump connections 62 between the first die 18 and the signal leads 12b associated with the second die 20 can be made as shown in FIG. 1B.

The structure, excluding portions of the lead frame 14 that will form terminal ends of the signal leads 12a, 12b and primary leads 16d, can be overmolded with first mold material 50a in a mold process step, as can be by transfer molding. The mold material 50a extends to the surface 14a of the lead frame.

In FIG. 2A, the subassembly thus including the lead frame 14, the insulating layer 38, the die 18, and first mold 50a can then be flipped over to facilitate attachment of the second die 20 to the opposite surface 14b of the lead frame. This step can include attachment of the insulating layer 40 to the primary conductor 16 and attachment of the die 20 to the insulating layer 40. Thereafter, wire bond connections 54 between the second die 20 and the signal leads 12b can be made to plated areas, or bond pads on the surface 14b of the lead frame as shown in FIG. 1A. In the case of inter-die diagnostics, wire bond connections 56 between the second die 20 and the signal leads 12a associated with the first die 18 can be made to plated areas, or bond pads on the surface 14b as shown in FIG. 1A.

In FIG. 2B, the entire structure, excluding portions of the lead frame 14 that will form terminal ends of the signal leads 12a, 12b and primary leads 16d, can be overmolded with mold material 50b in a second mold process step, following which terminal ends of primary conductor leads 16d and signal leads 12 can be bent. The mold material 50b extends to the surface 14b of the lead frame.

In an alternative two mold process, in FIG. 2C, flip-chip die 18 is attached to the surface 14a of the lead frame 14 by attaching the insulating layer 38 to the primary conductor 16 and soldering bumps or copper pillars 60 to plated areas of the surface 14a of the lead frame 14. In the case of inter-die diagnostics, bump connections 62 between the first die 18 and the signal leads 12b associated with the second die 20 can be made as shown in FIG. 1B.

The structure, excluding portions of the lead frame 14 that will form terminal ends of the signal leads 12a. 12b and primary leads 16d, can be overmolded with first mold material including mold portions 50a, 50a′ in a first mold process step, as can be by transfer molding. The mold portion 50a covers die 18 and extends to the surface 14a of the lead frame. The mold portion 50a′ covers a portion of the lead frame surface 14b in order to provide isolation to die 20. In embodiments, the mold material portion 50a′ can have a thickness of between 4-8 mils.

In FIG. 2D, the subassembly thus including the lead frame 14, the die 18, and mold portions 50a, 50a′ can then then be flipped over to facilitate attachment of the second die 20 to mold portion 50a′ as may be accomplished with a non-conductive epoxy, a wafer backside coating (WBC) material, or other attachment mechanism. In this fabrication method, insulation layer 40 is omitted and insulation between die 20 and lead frame 14 is instead provided by the mold portion 50a′. Thereafter, wire bond connections 54 between the second die 20 and the signal leads associated with the second die (e.g., signal leads 12b in FIG. 1A) can be made to plated areas, or bond pads on the surface 14a of the lead frame. In the case of inter-die diagnostics, wire bond connections 56 between the second die 20 and the signal leads 12a associated with the first die 18 can be made to plated areas, or bond pads on the surface 14b as shown in FIG. 1A.

In FIG. 2E, the entire structure, excluding portions of the lead frame 14 that will form terminal ends of the signal leads 12a, 12b and primary leads 16d, can be overmolded with mold material 50b in a second mold process step, following which terminals ends of primary conductor leads 16d and signal leads 12a, 12b can be bent. The mold material 50b extends to the surface 14b of the lead frame.

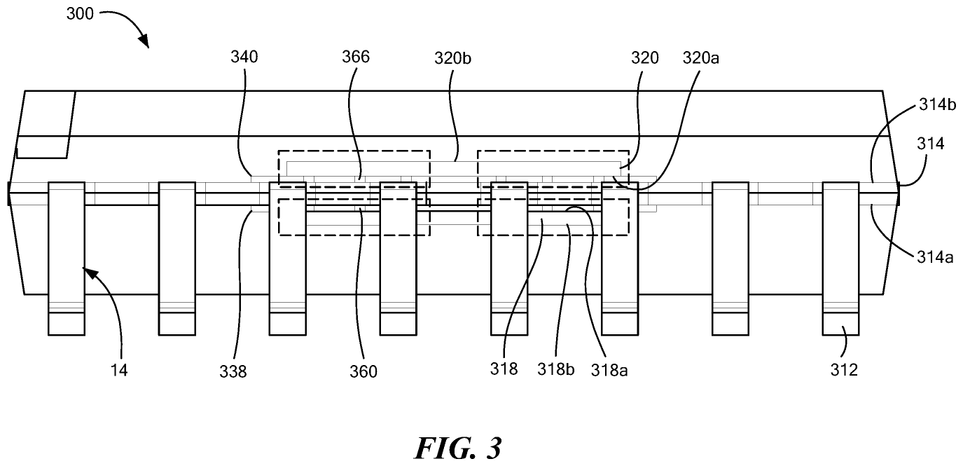

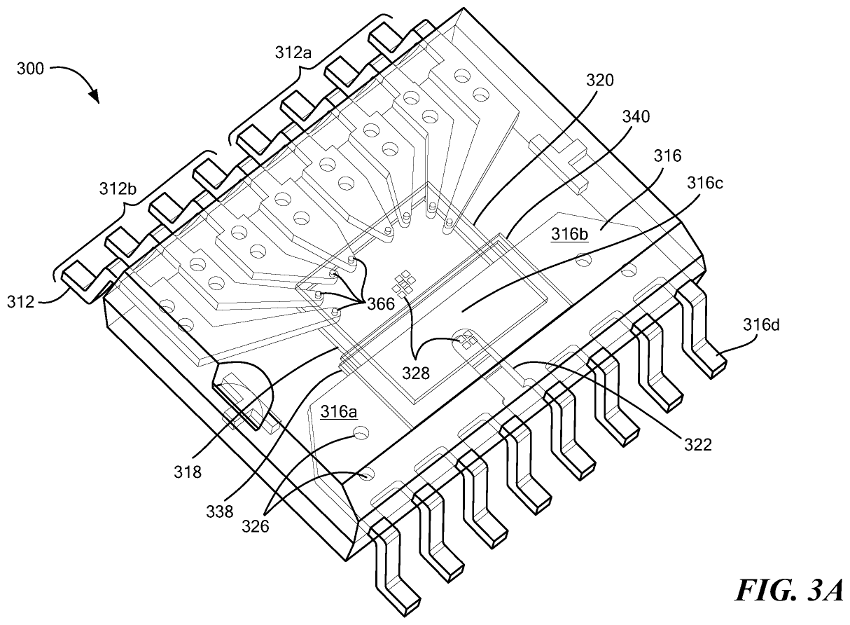

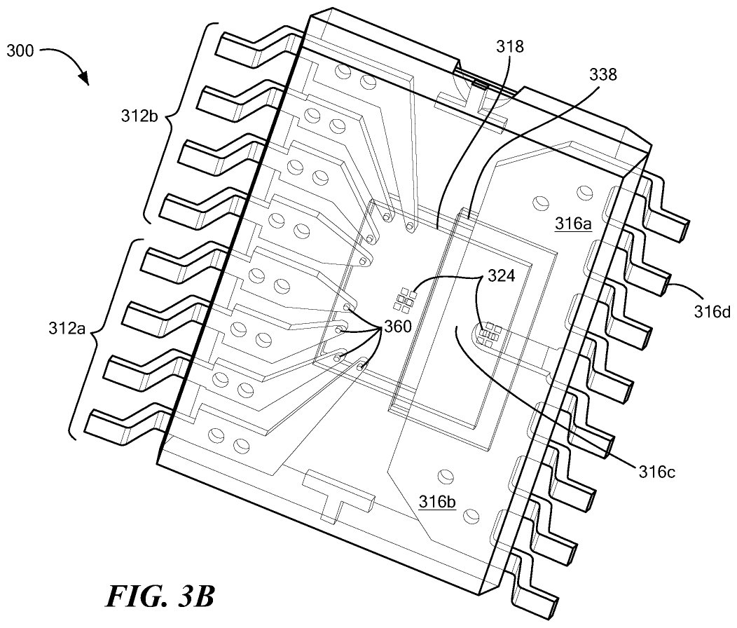

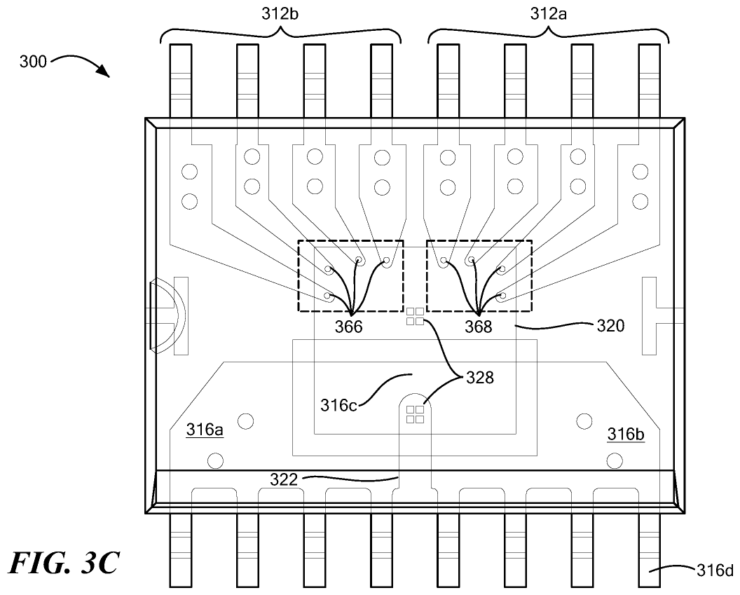

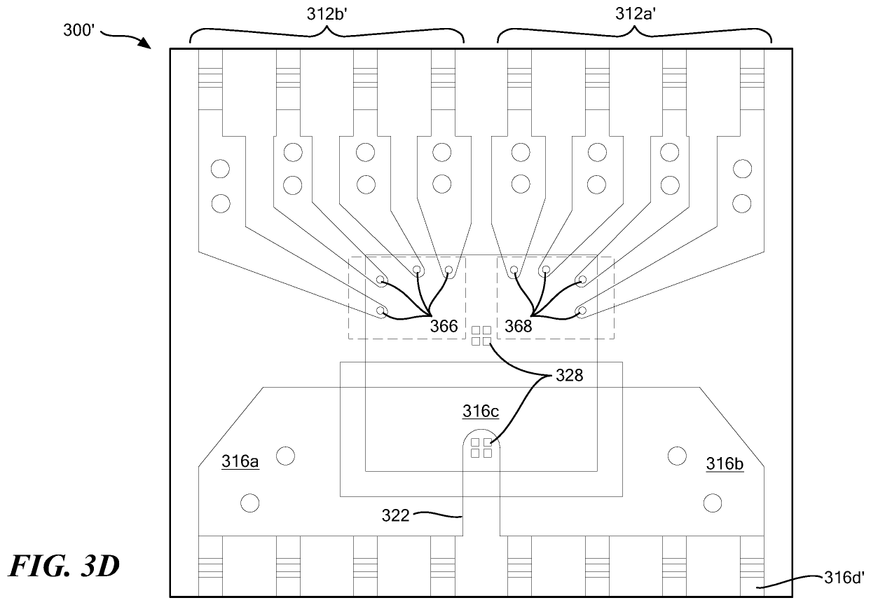

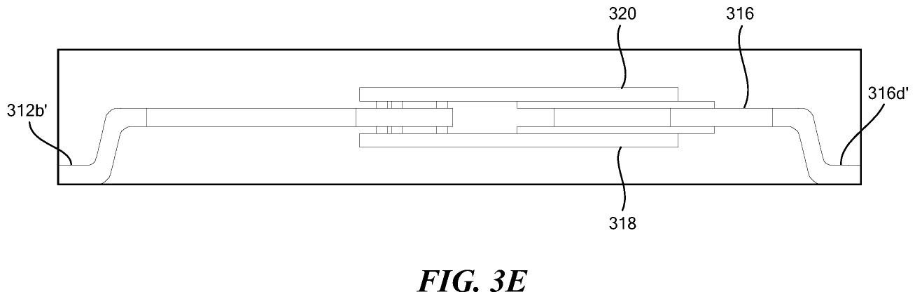

Referring to the various views of FIGS. 3-3C, a current sensor integrated circuit (IC) 300 includes a lead frame 314 having a first surface 314a and a second surface 314b opposite to the first surface, with a first semiconductor die 318 adjacent to the first surface 314a and a second semiconductor die 320 adjacent to the second surface 314b. The lead frame 314 further includes a primary conductor 316 and a plurality of signal leads, collectively labeled 312. Signal leads 312 include a first signal lead set 312a associated with the first die 318 and a second signal lead set 312b associated with the second die 320. It will be appreciated by those of ordinary skill in the art that although the lead frame 314 is shown to have eight signal leads, with four such leads forming the first signal lead set 312a and four such leads forming the second signal lead set 312b, other numbers, dimensions, spacing, and configurations of leads are possible.

The first semiconductor die 318 has a first surface 318a adjacent to the first surface 314a of the lead frame 314 and a second opposite surface 318b. The first semiconductor die 318 includes a first magnetic field sensing element 324, as may include one or more sensing elements such as a dual Hall element or a quad Hall element or one or more MR elements such as GMR or TMR elements as can be arranged in a bridge configuration and as may be used to implement differential magnetic field sensing, supported by the first surface 318a of the first semiconductor die 318 and configured to sense a magnetic field associated with a current through the primary conductor 316 to generate a first output signal indicative of the current for coupling to a first signal lead 312a. The second semiconductor die 320 has a first surface 320a adjacent to the second surface 314b of the lead frame 314 and a second opposite surface 320b. The second semiconductor die 320 includes a second magnetic field sensing element 328, as may include one or more sensing elements as can be arranged in a bridge configuration and as may be used to implement differential magnetic field sensing, supported by the second surface 320b of the second semiconductor die 320 and configured to sense the magnetic field associated with the current through the primary conductor 316 and generate a second output signal indicative of the current for coupling to a second signal lead 312b. It will be appreciated that although the first semiconductor die 318 is described as supporting a first magnetic field sensing element 324 and the second semiconductor die 320 is described as supporting a second magnetic field sensing element 328, in embodiments, it is possible for only one of the die 318, 320 to support one or more magnetic field sensing elements and the other die to support processing circuitry.

With this arrangement, both the first semiconductor die 318 and the second semiconductor die 320 are arranged in a so-called flip-chip configuration with which the respective sensing element 324, 328 is supported by a die surface 318a, 320a proximal to the lead frame 314. This arrangement permits the semiconductor die 318, 320 to be redundant in the sense that each die can detect the same magnetic field associated with current flow through the primary conductor 316 and provide a respective output signal indicative of the sensed current. Such redundant current sensing can be accomplished using identical sensing elements and/or processing circuitry on the two die 318, 320 or there can be one or more differences between the sensing elements and/or processing circuitry implemented by the two die 318, 320. Designing the two die 318, 320 with different sensing elements and/or processing circuitry can achieve so-called heterogeneous redundancy that can increase the level of safety integrity.

Advantageously, having one die 318 proximal to one surface 314a of the lead frame 314 and the other die 318 proximal to the other, opposite surface 314b of the lead frame permits substantially the same coupling of the magnetic field to each sensing element 324, 328 and thus, the two die 318, 320 can be used to provide redundant sensing for safety requirement compliance. In embodiments in which it is desired that both die 318, 320 detect different currents or ranges of currents, the processing circuitry on one or both die can be programmed to have different sensitivities.

The primary conductor 316 may have various shapes and dimensions to accommodate a range of current levels sought to be detected by the current sensor 300 and the desired IC package footprint. In general, primary conductor 316 includes an input portion 316a, an output portion 316b, and a thinned current path 316c between the input and output portions. In use, a current flow is established through the primary conductor 316 between the input and output portions 316a, 316b.

The input and output portions 316a, 316b of the primary conductor 316 can have respective terminal ends in the form of leads, collectively labeled 316d, configured for electrical connection to a printed circuit board (PCB) or other substrate on which the IC 300 is mounted. The leads 316d of the primary conductor 316 and signal leads 312 can take various forms, such as the illustrated leads that are bent to facilitate solder connection to a PCB or other substrate. Current sensor IC 300 can be considered an SOIC (Small Outline Integrated Circuit) package. Other package types, such as QFN (Quad-Flat No-Leads), or the DFN (Dual-Flat No-Leads) sensor IC 310′ of FIGS. 3D and 3E are possible.

The thinned current path 316c of the primary conductor 316 can have various shapes and other characteristics. Here, the thinned path 316c is established by a notch 322. Placement of the sensing elements 324, 328 relative to the thinned current path 316c and notch 322 can concentrate the magnetic field generated by current through the primary conductor 316 on the sensing elements. It will be appreciated that other shapes, dimensions, notches, and sensing element placement can be implemented to achieve concentration of the magnetic field.

In embodiments, the first magnetic field sensing element 324 can include one or more elements that are substantially vertically aligned with a first side of the notch 322 and one or more elements that are substantially vertically aligned with a second side of the notch 322. Similarly, the second magnetic field sensing element 328 can include one or more elements that are substantially vertically aligned with a first side of the notch 322 and one or more elements that are substantially vertically aligned with a second side of the notch 322. As current flows through the primary conductor 316, having magnetic field sensing elements 324, 328 positioned to the side of the conductor (rather than directly over or under the conductor) results in magnetic field with components perpendicular to the die 318, 320 such that the sensing elements may be planar Hall effect elements. In other embodiments, the magnetic field sensing element or elements may be positioned directly over or under the primary conductor 316 to sense magnetic field components parallel to the surface of die 318, 320, in which case sensing elements such as a vertical Hall element, a GMR, TMR, or AMR element may be used.

The lead frame 314 can be comprised of a conductive material, such as copper or copper alloy or Aluminum, and its features can be formed by various methods such as stamping.

Electrical isolation between the primary conductor 316 and the first semiconductor die 318 can be achieved with various mechanisms, such as with an insulating layer 338 disposed between the primary conductor and the first surface 318a of the first semiconductor die. Similarly, electrical isolation between the primary conductor 316 and the second semiconductor die 20 can be achieved with various mechanisms, such as with an insulating layer 340 disposed between the primary conductor and the first surface 320a of the second semiconductor die 320.

One or both of insulating layers 338, 340 can include an organic polymer such as polyimide, or an oxide insulating material like silicon dioxide in the form of a glass sheet, or ceramic. For example, insulating layers 338, 340 can be a polymer film, as may be provided in the form of a polyimide or Kapton® tape, as non-limiting examples. Insulating layers 338, 340 may include an adhesive layer, in which case the polymer film and the adhesive layer may be provided as a tape with which the insulating layers are attached to the lead frame 314.

Insulating layers 338, 340 can extend beyond the periphery of the respective semiconductor die 318, 320 and/or primary conductor 316 so as to achieve a required clearance specification. For example, in embodiments, the insulating layers 338, 340 may extend beyond the respective die 318, 320 and/or primary conductor 316 by a distance of at least 0.4 mm. The overall size and shape of the insulation layers 338, 340 can vary with the size/shape of the die 318, 320 and primary conductor 316.

Flip-chip configured semiconductor die 318, 320 can be electrically coupled to the lead frame 314 by various mechanisms, including bumps 360 as can be solder bumps or copper pillars, as non-limiting examples. For example, bumps 360 can electrically couple die 318 to lead frame surface 314a for coupling to leads 312a. Similarly, bumps 366 can electrically couple die 320 to lead frame surface 314b for coupling to leads 312b. The solder may be a Sn Pb solder or a lead less solder, such as an Indium solder. The first die 318 may have a higher reflow temperature for the conductive material than the second die 320 solder material. One or more bumps 360, 366 can be so-called “dummy” bumps, in that they provide only mechanical attachment and/or stability rather than both mechanical and electrical coupling.

According to an aspect of the disclosure, the dual-die current sensor IC 300 facilitates electrical connection between the die 318, 320 with which diagnostics can be implemented. As illustrated in FIG. 4, one or both of the die 318, 320 can include a diagnostic circuit having one or more diagnostic inputs coupled to a signal lead 312b, 312a associated with the other one of the first and second die and configured to generate a diagnostic signal indicative of a status of the other one of the first and second die. To this end, bumps 362 can electrically couple die 318 to signal leads 312b associated with the die 320 and/or bumps 368 can electrically couple die 320 to signal leads 312a associated with the die 318.

Insulating material 350 can take the form of a mold material configured to encapsulate the first and second semiconductor die 318, 320, and portions of the lead frame 314 in order to form the packaged current sensor IC 300. The mold material 350 is shown to illustrate elements encapsulated within the IC package 300. Various materials can be used to form the mold material 350, including, but not limited to a plastic material.

Portions of the lead frame 314 can include features configured to enhance adhesion of the mold material 350 to the lead frame, thereby serving as a “locking mechanism” to secure parts of the IC package together. Here, holes 326 through the primary conductor 316 and signal leads 312 can provide such a locking mechanism.

In some embodiments, fabrication of the current sensor 300 can be accomplished by first attaching the flip-chip die 318 to the surface 314a of the lead frame. This step can include attaching the insulating layer 338 to the primary conductor 316 and soldering bumps or copper pillars 360 to plated areas of the surface 314a of the lead frame 314 for electrical connection to signal leads 312a. In the case of inter-die diagnostics, bump connections 368 between the second die 20 and the signal leads 12a associated with the first die 318 can be made.

The subassembly thus including the lead frame 314, the insulating layer 338, and the die 318 can then be flipped over to facilitate attachment of the second die 320 to the surface 314b of the lead frame. This step can include attachment of the insulating layer 340 to the primary conductor 316 and soldering the solder bumps or copper pillars 366 to plated areas of the surface 314b of the lead frame 314. In the case of inter-die diagnostics, bump connections 362 between the first die 318 and the signal leads 312b associated with the second die 320 can be made.

The entire structure, excluding terminal ends of the signal leads 312 and primary leads 316d, can be overmolded with mold material 350 in a mold process step, following which terminal ends of primary conductor leads 316d and signal leads 312 can be bent, as shown. The mold material 350 can be formed by a transfer mold process, as may include a single mold process step. It will be appreciated by those of ordinary skill in the art that the order of the above-described steps can be varied. For example, the second die 320 can be attached to the lead frame before the first die 318.

Referring also FIGS. 3D and 3E, an alternative current sensor IC 300′ can be a DEN package, but in other respects can be the same as or similar to current sensor IC 300 (and thus, like reference numbers are used for like elements). To this end, the terminal ends of primary conductor leads 316d′ are conductive pads exposed from side and bottom surfaces of the package 310′ and the signal leads 312a′, 312b′ are likewise conductive pads exposed from side and bottom surfaces of the package 310′. Accordingly, as shown in the side view of FIG. 3E, the leads 312a′, 312b′, 316d′ are upset. In other respects, the DFN package of FIGS. 3D and 3E can be the same as the SOIC package of FIGS. 3-3C.

Referring to FIG. 4, an example current sensor IC includes a first semiconductor die 400 that may be the same as or similar to die 18, 318 and a second semiconductor die 500 as may be the same as or similar to die 20, 320. Also shown in FIG. 4 is a primary conductor 416 as may be the same as or similar to primary conductor 16, 316 that part of a lead frame that has die 400 adjacent to one surface and die 500 adjacent to an opposite surface.

Example elements of the current sensor IC including die 400 and die 500 are shown in connection with die 400. It will be appreciated that sensor 400 is presented as a non-limiting example of circuitry suitable for sensors 10, 300 according to the disclosure. Also, it will be appreciated however that die 500 can include like elements or can include different elements to implement heterogeneous redundancy and/or current sensing of different current levels or ranges.

Die 400 includes one or more magnetic field sensing elements, and here two sensing elements 412a, 412b. Sensing elements 412a, 412b can be Hall effect elements in which case the placement illustrated in FIGS. 1A-1C and 3A-3C on either side of the notch 22, 322 of the primary conductor 16, 316 is suitable to sense magnetic field components perpendicular to the die surface or sensing elements 412a, 412b can be other magnetic field transducer element types, such as magnetoresistive elements in which case it may be desirable to position the elements in vertical alignment with the primary conductor to sense magnetic field components parallel to the die surface.

Use of two or more sensing elements 412a, 412b permits differential magnetic field sensing, as may be advantageous to improve immunity (i.e., insensitivity) to common-mode stray magnetic fields. While differential sensing may be implemented, for example using two sensing elements as shown, in some embodiments, the each current sensor die 400, 500 can include only a single sensing element. Furthermore, it will also be appreciated that differential sensing can be implemented using more than two sensing elements and can include the use of sensing elements arranged in a bridge configuration.

Example current sensor die 400 has four pins in this embodiment, including a VCC (supply voltage) pin 404, a VIOUT (output signal) pin 402, and a GND (ground) pin 406. The VCC pin 408 is used for the input powered supply or supply voltage for the die 400. The VCC pin 404 can also be used for programming the current sensor die 400. A regulator 440 can be coupled to the VCC pin 404 and to the various components and sub-circuits of the die 400 to regulate the supply current. A power on reset circuit 444 can provide a regulated voltage to EEPROM and control logic circuit 430 upon power up.

The VIOUT pin 402 is used for providing the output signal for the die 500 to circuits and systems (not shown) and can take the form of an analog voltage proportional to the sensed current through the primary conductor 416. Although pin 402 is a voltage output, it is possible to have a current output. To this end, the VIOUT pin 402 can be coupled to a signal lead, such as a lead 12a, 12b, 312a, 312b. The VIOUT pin 402 can also be used for programming, such as programming the zero ampere output.

The sensor die 400 can include fault detection circuitry configured to generate a fault signal at a fault output pin 410 in order to provide an indication of a fault status of the die 400. As an example, a fault comparator 448 can detect the differential output voltage of amplifier 414 and can flag a fault to logic 454 if the differential voltage is considered to be out of a specified range for the current sensing application in order to thereby detect an overcurrent condition as may be the result of a short circuit event. Fault delay logic 454 can be coupled to a driver 458 with which the fault signal is provided at fault pin 410 in order to establish a minimum time period during which a fault must be present before the fault pin 410 is latched.

Magnetic field signals generated by the magnetic field sensing elements 412a, 412b are coupled to a dynamic offset cancellation circuit 412, which is further coupled to an amplifier 414. Dynamic offset cancellation circuit 412 may take various forms including chopping circuitry and may function in conjunction with offset control 434 to remove offset that can be associated with the magnetic field sensing elements 412a, 412b and/or the amplifier 414. For example, offset cancellation circuit 412 can include switches configurable to drive the magnetic field sensing elements (e.g., Hall plates) in two or more different directions such that selected drive and signal contact pairs are interchanged during each phase of the chopping clock signal and offset voltages of the different driving arrangements tend to cancel.

A programming control circuit 422 is coupled between the VCC pin 404 and EEPROM and control logic 430 to provide appropriate control to the EEPROM and control logic circuit. EEPROM and control logic circuit 430 determines any application-specific coding and can be erased and reprogrammed using a pulsed voltage. A sensitivity control circuit 424 can be coupled to the amplifier 414 to generate and provide a sensitivity control signal to the amplifier 414 to adjust a sensitivity and/or operating voltage of the amplifier. The offset control circuit 434 can generate and provide an offset signal to a driver circuit 418 (which may be an amplifier) through a resistive network 426 to adjust the sensitivity and/or operating voltage of the driver circuit. Temperature compensation can be achieved using temperature data acquired from EEPROM and control logic circuit 430 via a temperature sensor 415 and perform necessary calculations to compensate for changes in temperature, if needed.

According to an aspect of the disclosure, the described dual-die current sensor ICs can facilitate electrical connection between the two die with which diagnostics can be implemented. To this end, one or both of the first semiconductor die 400 and the second semiconductor die 500 can include a diagnostic circuit having one or more inputs (i.e., diagnostic input pins) coupled to a respective signal lead associated with the other one of the first and second die and configured to generate a diagnostic signal indicative of a status of the other one of the first and second die. As shown for die 400, fault comparator 448 can be used to detect a fault associated with die 500. For example, the operation of comparator 448 can be multiplexed by a multiplexer 450 in order to selectively detect a fault associated with the die 400 itself or one or more faults associated with the die 500. Alternatively, additional fault comparators or other fault detection circuitry can be provided on die 400 to detect a fault associated with die 500.

In the context of detecting a fault associated with die 500, die 400 can include one or more diagnostic input pins 408a, 408b, 408c, each of which is electrically coupled to a respective signal lead associated with die 500. For example, diagnostic input pin 408a can be coupled to the VCC supply voltage pin 508 of die 500, diagnostic input pin 408b can be coupled to the VIOUT output signal pin 502 of die 500, and diagnostic input pin 408c can be coupled to the ground pin 506 of die 500 in order to detect a fault at any such pin. A fault associated with die 500 can thus be reported by die 400 via the fault pin 410.

Although die 400 is shown to include three diagnostic input pins 408a-408c, each electrically coupled to a signal pin associated with die 500, other numbers of diagnostic input pins can be provided. Furthermore, in the context of a current sensor IC in which each die has eight signal pins (e.g., die 18, 20), rather than the illustrated seven signal pins associated with die 400, the eighth pin can be a so-called dummy pin, with no electrical connection. Furthermore, although not shown in FIG. 4 for simplicity of illustration, die 500 can include diagnostic circuitry and one or more diagnostic input pins with which connection can be made to signal leads 402, 404, 406, 410 associated with die 400 in order to thereby detect a fault condition associated with die 400.

It will be appreciated by those of ordinary skill in the art that while die 400 is described as being the same as or similar to die 18, 318 (and thus, in a flip-chip orientation) and die 500 is described as being the same as or similar to die 20, 320 (and thus, in either a die up orientation in the case of die 20 or in a flip-chip orientation in the case of die 320), in embodiments implementing the above-described inter-die diagnostics, it is possible to have both die 400, 500 in die-up orientations.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of elements can refer to either a direct or an indirect coupling, and a positional relationship between elements can be a direct or indirect positional relationship.

The following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

The terms “one or more” and “at least one” indicate any integer number greater than or equal to one, i.e., one, two, three, four, etc.; though, where context admits, those terms may indicate fractional values. The term “plurality” indicates any integer number greater than one. The term “connection” can include an indirect “connection” and a direct “connection.”

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The term “substantially” may be used to refer to values that are within +20% of a comparative measure in some embodiments, within +10% in some embodiments, within +5% in some embodiments, and yet within +2% in some embodiments.

Having described preferred embodiments, it will now become apparent to one of ordinary skill in the art that other embodiments incorporating their concepts may be used. Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims. All publications and references cited in this patent are expressly incorporated by reference in their entirety.

It is felt therefore that these embodiments should not be limited to disclosed embodiments, but rather should be limited only by the spirit and scope of the appended claims.

1. A current sensor integrated circuit (IC) comprising:
a lead frame having a first surface and a second surface opposite to the first surface and comprising a primary conductor and signal leads;
a first semiconductor die having a first surface adjacent to the first surface of the lead frame and a second opposite surface, wherein the first semiconductor die comprises a first magnetic field sensing element supported by the first surface of the first semiconductor die and configured to sense a magnetic field associated with a current through the primary conductor and to generate a first output signal indicative of the current for coupling to a first signal lead; and
a second semiconductor die having a first surface adjacent to the second surface of the lead frame and a second opposite surface, wherein the second semiconductor die comprises a second magnetic field sensing element supported by the second surface of the second semiconductor die and configured to sense the magnetic field associated with the current through the primary conductor and to generate a second output signal indicative of the current for coupling to a second signal lead.

2. The current sensor IC of claim 1 further comprising a solder bump or copper pillar to couple the first output signal to the first signal lead and a wire bond to couple the second output signal to the second signal lead.

3. The current sensor IC of claim 1 further comprising a mold material configured to enclose the first semiconductor die, the second semiconductor die, and a portion of the lead frame to form a package.

4. The current sensor IC of claim 1 further comprising a first mold material to enclose the first semiconductor die and a portion of the lead frame, wherein the second semiconductor die is attached to the first mold material and wherein the current sensor IC further comprises a second mold material to enclose the second semiconductor die.

5. The current sensor IC of claim 1 wherein the first output signal is indicative of the current within a first range of currents, wherein the second output signal is indicative of the current within a second range of currents, and wherein the first range of currents is the same as or different than the second range of currents.

6. The current sensor IC of claim 1 further comprising:
a first insulation structure disposed between the primary conductor and the first semiconductor die; and
a second insulation structure disposed between the primary conductor and the second semiconductor die.

7. The current sensor IC of claim 6 wherein each of the first insulation structure and the second insulation structure comprise a polymer film.

8. The current sensor IC of claim 7 wherein each of the first insulation structure and the second insulation structure further comprises an adhesive layer.

9. The current sensor IC of claim 8 wherein the polymer film and the adhesive layer are provided as a tape.

10. The current sensor IC of claim 9 wherein the tape extends beyond a periphery of the first semiconductor die and the second semiconductor die.

11. The current sensor IC of claim 9 wherein the tape extends beyond the primary conductor adjacent to the signal leads by 0.4 mm.

12. The current sensor IC of claim 6 further comprising an attachment material to attach the first semiconductor die to the first insulation structure and to attach the second semiconductor die to the second insulation structure.

13. The current sensor IC of claim 12 wherein the attachment material comprises a non-conductive adhesive.

14. The current sensor IC of claim 1 wherein the primary conductor comprises at least one notch and wherein the first magnetic field sensing element is substantially vertically aligned with a first side of the at least one notch and the second magnetic field sensing element is substantially vertically aligned with a second side of the at least one notch.

15. The current sensor IC of claim 1 wherein the signal leads comprise signal leads associated with the first semiconductor die and signal leads associated with the second semiconductor die, wherein one or both of the first semiconductor die and the second semiconductor die further comprises a diagnostic circuit having an input coupled to a signal lead associated with the other one of the first semiconductor die and the second semiconductor die and configured to generate a diagnostic signal indicative of a status of the other one of the first semiconductor die and the second semiconductor die.

16. A current sensor integrated circuit (IC) comprising:
a lead frame having a first surface and a second surface opposite to the first surface and comprising a primary conductor and signal leads;
a first semiconductor die having a first surface adjacent to the first surface of the lead frame and a second opposite surface, wherein the first semiconductor die comprises a first magnetic field sensing element supported by the first surface of the first semiconductor die and configured to sense a magnetic field associated with a current through the primary conductor and to generate a first output signal indicative of the current for coupling to a first signal lead; and
a second semiconductor die having a first surface adjacent to the second surface of the lead frame and a second opposite surface, wherein the second semiconductor die comprises a second magnetic field sensing element supported by the first surface of the second semiconductor die and configured to sense the magnetic field associated with the current through the primary conductor and to generate a second output signal indicative of the current for coupling to a second signal lead.

17. The current sensor IC of claim 16 further comprising a first solder bump or copper pillar to couple the first output signal to the first signal lead and a second solder bump or copper pillar to couple the second output signal to the second signal lead.

18. The current sensor IC of claim 16 further comprising a mold material configured to enclose the first semiconductor die, the second semiconductor die, and a portion of the lead frame to form a package.

19. A method of manufacturing a current sensor integrated circuit (IC) comprising:
providing a lead frame having a first surface and a second surface opposite to the first surface with a primary conductor and signal leads;
positioning a first semiconductor die adjacent to the first surface of the lead frame, wherein the first semiconductor die is associated with a first plurality of the signal leads and comprises a first magnetic field sensing element to sense a magnetic field associated with a current through the primary conductor and to generate a first output signal indicative of the current for coupling to one or more of the first plurality of signal leads; and
positioning a second semiconductor die adjacent to the second surface of the lead frame, wherein the second semiconductor die is associated with a second plurality of the signal leads and comprises a second magnetic field sensing element to sense the magnetic field associated with the current through the primary conductor and to generate a second output signal indicative of the current for coupling to one or more of the second plurality of signal leads, wherein the first semiconductor die comprises a diagnostic circuit having an input coupled to one or more of the second plurality of signal leads and configured to generate a first diagnostic signal indicative of a status of the second semiconductor die.

20. The method of claim 19 wherein the one or more of the second plurality of signal leads comprises one or more of a supply connection, a ground connection, or an output connection.
